(19) United States
(12) Patent Application Publication
(10) Pub. No.: US 2025/0364439 A1
(43) Pub. Date: Nov. 27, 2025

(54) SEMICONDUCTOR PACKAGE AND METHODS OF MANUFACTURING

(71) Applicant: Taiwan Semiconductor Manufacturing Company, Ltd., Hsinchu (TW)

(72) Inventors: Po-Chen LAI, Hsinchu (TW); Ming-Chih YEW, Hsinchu City (TW); Shu-Shen YEH, Taoyuan City (TW); Po-Yao LIN, Zhudong Township (TW); Shin-Puu JENG, Hsinchu (TW)

(21) Appl. No.: 19/291,160

(22) Filed: Aug. 5, 2025

Related U.S. Application Data
(62) Division of application No. 17/805,109, filed on Jun. 2, 2022.

(51) Int. Cl. H01L 23/00; H01L 21/48; H01L 23/538; H01L 23/552; H01L 25/18

(52) U.S. Cl. CPC H01L 23/562; H01L 21/4857; H01L 23/5383; H01L 23/552; H01L 25/18; H01L 24/13; H01L 2224/13111; H01L 2224/13116; H01L 2224/13139; H01L 2224/13144; H01L 2224/13147; H01L 2224/13155; H01L 2224/13164; H01L 2924/014

(57) ABSTRACT

Some implementations described herein provide techniques and apparatuses for a semiconductor package. The semiconductor package, which may correspond to a high performance computing package, includes a reinforcement structure that is embedded in a substrate of the semiconductor package. The reinforcement structure may increase a rigidity of the semiconductor package so that a warpage is reduced and a coplanarity between the substrate and a printed circuit board is maintained during a surface mount process. Reducing the warpage may increase a robustness of connection structures between an interposer and the substrate. Additionally, maintaining the coplanarity reduces a likelihood that connection structures at a bottom surface of the substrate will fail to adequately solder or attach to lands of the printed circuit board during the surface mount process. In this way, a likelihood of opens and/or shorts between the semiconductor package and the printed circuit board is reduced and a robustness of the semiconductor package may be increased to improve an overall yield of a product including the semiconductor package.

### RELATED APPLICATION

This application is a division of U.S. patent application Ser. No. 17/805,109, filed Jun. 2, 2022, which is incorporated herein by reference in its entirety.

### BACKGROUND

A high performance computing (HPC) semiconductor package may include one or more integrated circuit (IC) dies, or chips, from a semiconductor wafer, such as a system-on-chip (SoC) IC die, a dynamic random access memory (DRAM) IC die, or a high bandwidth memory (HBM) IC die. The HPC semiconductor package may include an interposer that provides an interface between the one or more IC dies and a substrate. The HPC semiconductor package further includes one or more connection structures to provide electrical connectivity for signaling between the one or more IC dies, the interposer, and the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example implementation of a semiconductor package described herein.

FIGS. 3A-3F and 4A-4C are diagrams of an example implementation described herein.

FIG. 5 is a diagram of example components of one or more devices of FIG. 1 described herein.

FIG. 6 is a flowchart of an example process associated with forming a semiconductor package described herein.

FIGS. 7A-7E are diagrams of an example implementation described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor package includes one or more IC dies, an interposer, a substrate, and a stiffener structure. The interposer, the substrate, and/or the stiffener structure may each include a different (e.g., mismatched) coefficient of thermal expansion (CTE). In some cases, a size of the interposer in combination with the different CTEs may cause the semiconductor package to warp under a thermal load. For example, a temperature of a surface mount (SMT) process during which the semiconductor package is mounted to a circuit board may introduce lateral stresses that cause the semiconductor package to warp. Such warpage may reduce a coplanarity between the substrate (and connection structures on a bottom surface of the substrate) and the circuit board, causing electrical opens and/or shorts between the connection structures on the bottom surface of the substrate and the circuit board. Additionally, or alternatively, the warpage may cause damage to connection structures between the interposer and the substrate.

Some implementations described herein provide techniques and apparatuses for a semiconductor package. The semiconductor package, which may correspond to a high performance computing (HPC) package, includes a reinforcement structure that is embedded in a substrate of the semiconductor package. The reinforcement structure may increase a rigidity of the substrate, and/or the semiconductor package, so that a coplanarity between the substrate and a circuit board is maintained during an SMT process and so that a warpage of the semiconductor package is reduced.

Maintaining the coplanarity reduces a likelihood that connection structures at a bottom surface of the substrate will fail to adequately solder or attach to lands of the circuit board during the SMT process. Additionally, reducing the warpage may increase a robustness of connection structures formed between the interposer and the substrate. In this way, a likelihood of opens and/or shorts between the semiconductor package and the circuit board is reduced and a robustness of the semiconductor package may be increased to improve an overall yield of a product including the semiconductor package.

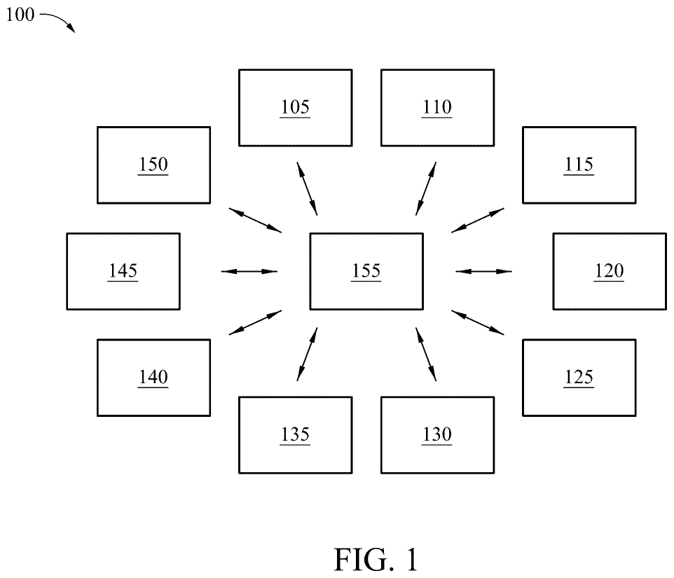

FIG. 1 is a diagram of an example environment 100 in which systems and/or methods described herein may be implemented. As shown in FIG. 1, environment 100 may include a plurality of semiconductor processing tool sets 105-150 and a transport tool set 155. The plurality of semiconductor processing tool sets 105-150 may include a redistribution layer (RDL) tool set 105, a planarization tool set 110, an connection tool set 115, an automated test equipment (ATE) tool set 120, a singulation tool set 125, a die-attach tool set 130, an encapsulation tool set 135, a printed circuit board (PCB) tool set 140, a surface mount (SMT) tool set 145, and a finished goods tool set 150. The semiconductor processing tool sets 105-150 of example environment 100 may be included in one or more facilities, such as a semiconductor clean or semi-clean room, a semiconductor foundry, a semiconductor processing facility, an outsourced assembly and test (OSAT) facility, and/or a manufacturing facility, among other examples.

In some implementations, the semiconductor processing tool sets 105-150, and operations performed by the semiconductor processing tool sets 105-150, are distributed across multiple facilities. Additionally, or alternatively, one or more of the semiconductor processing tool sets 105-150 may be subdivided across the multiple facilities. Sequences of operations performed by the semiconductor processing tool sets 105-150 may vary based on a type of the semiconductor package or a state of completion of the semiconductor package.

One or more of the semiconductor processing tool sets 105-150 may perform a combination of operations to assemble a semiconductor package (e.g., attach one or more IC dies to a substrate, where the substrate provides an external connectivity to a computing device, among other examples). Additionally, or alternatively, one or more of the semiconductor processing tool sets 105-150 may perform a combination of operations to ensure a quality and/or a reliability of the semiconductor package (e.g., test and sort the one or more IC dies, and/or the semiconductor package, at various stages of manufacturing).

The semiconductor package may correspond to a type of semiconductor package. For example, the semiconductor package may correspond to a flipchip (FC) type of semiconductor package, a ball grid array (BGA) type of semiconductor package, a multi-chip package (MCP) type of semiconductor package, or a chip scale package (CSP) type of semiconductor package. Additionally, or alternatively, the semiconductor package may correspond to a plastic leadless chip carrier (PLCC) type of semiconductor package, a system-in-package (SIP) type of semiconductor package, a ceramic leadless chip carrier (CLCC) type of semiconductor package, or a thin small outline package (TSOP) type of semiconductor package, among other examples.

The RDL tool set 105 includes one or more tools capable of forming one or more layers and patterns of materials (e.g., dielectric layers, conductive redistribution layers, and/or vertical connection access structures (vias), among other examples) on a semiconductor substrate (e.g., a semiconductor wafer, among other examples). The RDL tool set 105 may include a combination of one or more photolithography tools (e.g., a photolithography exposure tool, a photoresist dispense tool, a photoresist develop tool, among other examples), a combination of one or more etch tools (e.g., a plasma-based etched tool, a dry-etch tool, or a wet-etch tool, among other examples), and one or more deposition tools (e.g., a chemical vapor deposition (CVD) tool, a physical vapor deposition (PVD) tool, an atomic layer deposition (ALD) tool, or a plating tool, among other examples). In some implementations, the example environment 100 includes a plurality of types of such tools as part of RDL tool set 105.

The planarization tool set 110 includes one or more tools that are capable of polishing or planarizing various layers of the semiconductor substrate (e.g., the semiconductor wafer). The planarization tool set 110 may also include tools capable of thinning the semiconductor substrate. The planarization tool set 110 may include a chemical mechanical planarization (CMP) tool or a lapping tool, among other examples. In some implementations, the example environment 100 includes a plurality of types of such tools as part of the planarization tool set 110.

The connection tool set 115 includes one or more tools that are capable of forming connection structures (e.g., electrically-conductive structures) as part of the semiconductor package. The connection structures formed by the connection tool set 115 may include a wire, a stud, a pillar, a bump, or a solderball, among other examples. The connection structures formed by the connection tool set 115 may include materials such as a gold (Au) material, a copper (Cu) material, a silver (Ag) material, a nickel (Ni) material, a tin (Sn) material, or a palladium (Pd) material, among other examples. The connection tool set 115 may include a bumping tool, a wirebond tool, or a plating tool, among other examples. In some implementations, the example environment 100 includes a plurality of types of such tools as part of the connection tool set 115.

The ATE tool set 120 includes one or more tools that are capable of testing a quality and a reliability of the one or more IC dies and/or the semiconductor package (e.g., the one or more IC dies after encapsulation). The ATE tool set 120 may perform wafer testing operations, known good die (KGD) testing operations, semiconductor package testing operations, or system-level (e.g., a circuit board populated with one or more semiconductor packages and/or one or more IC dies) testing operations, among other examples. The ATE tool set 120 may include a parametric tester tool, a speed tester tool, and/or a burn-in tool, among other examples. Additionally, or alternatively, the ATE tool set 120 may include a prober tool, probe card tooling, test interface tooling, test socket tooling, a test handler tool, burn-in board tooling, and/or a burn-in board loader/unloader tool, among other examples. In some implementations, the example environment 100 includes a plurality of types of such tools as part of the ATE tool set 120.

The singulation tool set 125 includes one or more tools that are capable of singulating (e.g., separating, removing) the one or more IC dies or the semiconductor package from a carrier. For example, the singulation tool set 125 may include a dicing tool, a sawing tool, or a laser tool that cuts the one or more IC dies from the semiconductor substrate. Additionally, or alternatively, the singulation tool set 125 may include a trim-and-form tool that excises the semiconductor package from a leadframe. Additionally, or alternatively, the singulation tool set 125 may include a router tool or a laser tool that removes the semiconductor package from a strip or a panel of an organic substrate material, among other examples. In some implementations, the example environment 100 includes a plurality of types of such tools as part of the singulation tool set 125.

The die-attach tool set 130 includes one or more tools that are capable of attaching the one or more IC dies to the interposer, the leadframe, and/or the strip of the organic substrate material, among other examples. The die-attach tool set 130 may include a pick-and-place tool, a taping tool, a reflow tool (e.g., a furnace), a soldering tool, or an epoxy dispense tool, among other examples. In some implementations, the example environment 100 includes a plurality of types of such tools as part of the die-attach tool set 130.

The encapsulation tool set 135 includes one or more tools that are capable of encapsulating the one or more IC dies (e.g., the one or more IC dies attached to the interposer, the leadframe, or the strip of organic substrate material). For example, the encapsulation tool set 135 may include a molding tool that encapsulates the one or more IC dies in a plastic molding compound. Additionally, or alternatively, the encapsulation tool set 135 may include a dispense tool that dispenses an epoxy polymer underfill material between the one or more IC dies and an underlying surface (e.g., the interposer or the strip of organic substrate material, among other examples). In some implementations, the example environment 100 includes a plurality of types of such tools as part of the encapsulation tool set 135.

The PCB tool set 140 incudes one or more tools that are capable of forming a PCB having one or more layers of electrically-conductive traces. The PCB tool set 140 may form a type of PCB, such as a single layer PCB, a multi-layer PCB, or a high density connection (HDI) PCB, among other examples. In some implementations, the PCB tool set 140 forms the interposer and/or the substrate using one or more layers of a buildup film material and/or fiberglass reinforced epoxy material. The PCB tool set 140 may include a laminating tool, a plating tool, a photoengraving tool, a laser cutting tool, a pick-and-place tool, an etching tool, a dispense tool, a bonding tool, and/or a curing tool (e.g., a furnace) among other examples. In some implementations, the example environment 100 includes a plurality of types of such tools as part of the PCB tool set 140.

The SMT tool set 145 includes one or more tools that are capable of mounting the semiconductor package to a circuit board (e.g., a central processing unit (CPU) PCB, a memory module PCB, an automotive circuit board, and/or a display system board, among other examples). The SMT tool set 145 may include a stencil tool, a solder paste printing tool, a pick-and-place tool, a reflow tool (e.g., a furnace), and/or an inspection tool, among other examples. In some implementations, the example environment 100 includes a plurality of types of such tools as part of the SMT tool set 145.

The finished goods tool set 150 includes one or more tools that are capable of preparing a final product including the semiconductor package for shipment to a customer. The finished goods tool set 150 may include a tape-and-reel tool, a pick-and-place tool, a carrier tray stacking tool, a boxing tool, a drop-testing tool, a carousel tool, a controlled-environment storage tool, and/or a scaling tool, among other examples. In some implementations, the example environment 100 includes a plurality of types of such tools as part of the finished goods tool set 150.

The transport tool set 155 includes one or more tools that are capable of transporting work-in-process (WIP) between the semiconductor processing tools 105-150. The transport tool set 155 may be configured to accommodate one or more transport carriers such a wafer transport carrier (e.g., a wafer cassette or a front opening unified pod (FOUP), among other examples), a die carrier transport carrier (e.g., a film frame, among other examples), and/or a package transport carrier (e.g., a joint electron device engineering (JEDEC) tray or a carrier tape reel, among other examples). The transport tool set 155 may also be configured to transfer and/or combine WIP amongst transport carriers. The transport tool set 155 may include a pick-and-place tool, a conveyor tool, a robot arm tool, an overhead hoist transport (OHT) tool, an automated materially handling system (AMHS) tool, and/or another type of tool. In some implementations, the example environment 100 includes a plurality of types of such tools as part of the transport tool set 155.

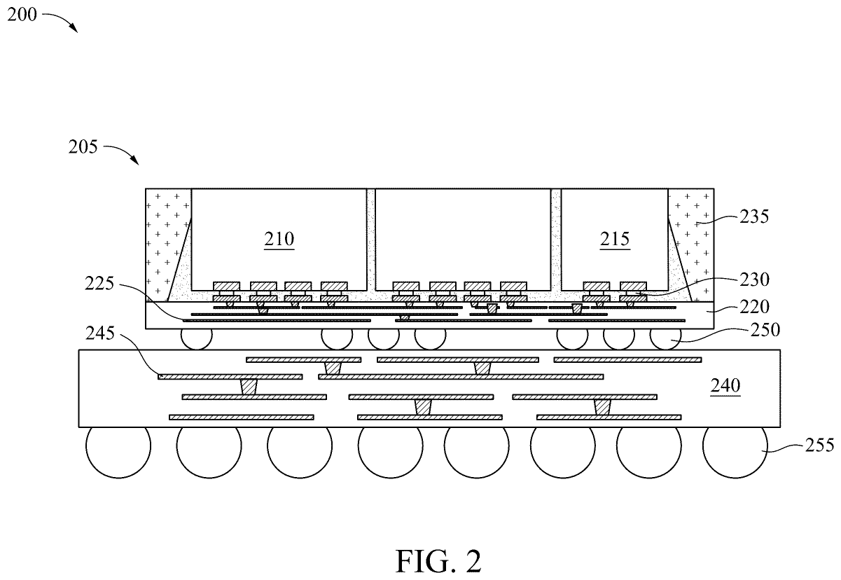

One or more of the semiconductor processing tool sets 105-150 may perform a series of operations to form one or more portions of a semiconductor package. As described in greater detail in connection with FIGS. 2-6, and elsewhere herein, the series of operations may include forming a bottom layer of a substrate including first electrically-conductive traces routed through a first dielectric material, forming a binding material layer over the bottom layer, and forming a reinforcement structure in the binding material layer to increase a rigidity of the substrate. The series of operations further includes forming a top layer of the substrate including second electrically-conductive traces routed through a second dielectric material over the binding material layer and curing the bottom layer, the binding material layer, the reinforcement structure, and the top layer to form the substrate.

The number and arrangement of tool sets shown in FIG. 1 are provided as one or more examples. In practice, there may be additional tool sets, different tool sets, or differently arranged tool sets than those shown in FIG. 1. Furthermore, two or more tool sets shown in FIG. 1 may be implemented within a single tool set, or a tool set shown in FIG. 1 may be implemented as multiple, distributed tool sets. Additionally, or alternatively, one or more tool sets of environment 100 may perform one or more functions described as being performed by another tool set of environment 100.

FIG. 2 is a diagram of an example implementation 200 of a semiconductor package 205 described herein. In some implementations, the semiconductor package 205 corresponds to a high-performance computing (HPC) semiconductor package.

The semiconductor package 205 may include one or more IC dies (e.g., the system-on-chip (SoC) IC die 210 and/or the dynamic random access memory (DRAM) IC die 215, among other examples). The semiconductor package 205 may include an interposer 220 having one or more layers of electrically-conductive traces 225. The interposer 220 may include one or more layers of a dielectric material, such as a ceramic material or a silicon material. In some implementations, the interposer 220 corresponds to a PCB including layers of a glass-reinforced epoxy laminate material and/or a pre-preg material (e.g., a composite fiber/resin/epoxy material), among other examples. Additionally, or alternatively, one or more layers of the interposer 220 may include a buildup film material.

The electrically-conductive traces 225 may include one or more materials such as a gold (Au) material, a copper (Cu) material, a silver (Ag) material, a nickel (Ni) material, a tin (Sn) material, or a palladium (Pd) material, among other examples. In some implementations, the interposer 220 includes one or more conductive vertical access connection structures (vias) that connect one or more layers of the electrically-conductive traces 225.

As shown in FIG. 2, the SoC IC die 210 and the DRAM IC die 215 are connected (e.g., mounted) to the interposer 220 using a plurality of connection structures 230. The connection structures 230 may include one or more combinations of a stud, a pillar, a bump, or a solderball, among other examples. The connection structures 230 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The connection structures 230 may connect lands (e.g., pads) on bottom surfaces of the SoC IC die 210 and the DRAM IC die 215 to lands on a top surface of the interposer 220. In some implementations, the connection structures 230 may include one or more electrical connections for signaling (e.g., corresponding lands of the SoC IC die 210, the DRAM IC die 215, and the interposer 220 are electrically connected to respective circuitry and/or traces of the SoC IC die 210, the DRAM IC die 215, and the interposer 220).

In some implementations, the connection structures 230 may include one or more mechanical connections for attachment purposes and/or spacing purposes (e.g., corresponding lands of the SoC IC die 210, the DRAM IC die 215, and the interposer 220 are not electrically connected to respective circuitry and/or traces of the SoC IC die 210, the DRAM IC die 215, and the interposer 220). In some implementations, one or more of the connection structures 230 may function both electrically and mechanically.

A mold compound 235 may encapsulate one or more portions of the semiconductor package 205, including portions of the SoC IC die 210 and/or the DRAM IC die 215. The mold compound 235 (e.g., a plastic mold compound, among other examples) may protect the SoC IC die 210 and/or the DRAM IC die 215 from damage during manufacturing of the semiconductor package 205 and/or during field use of the semiconductor package 205.

The semiconductor package 205 may include a substrate 240 having one or more layers of electrically-conductive traces 245. The substrate 240 may include one or more layers of a dielectric material, such as a ceramic material or a silicon material. In some implementations, the substrate 240 corresponds to a PCB including layers of a glass-reinforced epoxy laminate material and/or a pre-preg material (e.g., a composite fiber/resin/epoxy material), among other examples. Additionally, or alternatively, one or more layers of the substrate 240 may include a buildup film material.

The electrically-conductive traces 245 may include one or more materials such as a gold (Au) material, a copper (Cu) material, a silver (Ag) material, a nickel (Ni) material, a tin (Sn) material, or a palladium (Pd) material, among other examples. In some implementations, the substrate 240 includes one or more conductive vertical access connection structures (vias) that connect one or more layers of the electrically-conductive traces 245.

As shown in FIG. 2, the interposer 220 is connected (e.g., mounted) to the substrate 240 using a plurality of connection structures 250. The connection structures 250 may include one or more combinations of a stud, a pillar, a bump, or a solderball, among other examples. In some implementations, the connection structures 250 correspond to controlled collapse chip connection (C4) connection structures. The connection structures 250 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The connection structures 250 may connect lands (e.g., pads) on a bottom surface of the interposer 220 to lands on a top surface of the substrate 240. In some implementations, the connection structures 250 may include one or more electrical connections for signaling (e.g., corresponding lands of the interposer 220 and the substrate 240 are electrically connected to respective circuitry and/or traces of the interposer 220 and the substrate 240). In some implementations, the connection structures 250 may include or more mechanical connections for attachment purposes and/or spacing purposes (e.g., corresponding lands of the interposer 220 and the substrate 240 are not electrically connected to respective circuitry and/or traces of the interposer 220 and the substrate 240). In some implementations, one or more of the connection structures 250 may function both electrically and mechanically.

The semiconductor package 205 may include a plurality of connection structures 255 connected to lands (e.g., pads) on a bottom surface of the substrate 240. The connection structures 255 may include one or more combinations of a stud, a pillar, a bump, or a solderball, among other examples. The connection structures 255 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free). In some implementations, the connection structures 255 correspond to C4 connection structures.

The connection structures 255 may be used to attach the semiconductor package 205 (e.g., the substrate 240) to a circuit board (not shown) using a surface mount (SMT) process. In some implementations, the connection structures 255 may provide an electrical connection for signaling (e.g., corresponding lands of the substrate 240 and the circuit board may be electrically connected to respective circuitry and/or traces of the substrate 240 and the circuit board). In some implementations, the connection structures 255 may provide a mechanical connection to the circuit board for attachment purposes and/or spacing purposes (e.g., corresponding lands of the substrate 240 and the circuit board may not be electrically connected to respective circuitry and/or traces of the substrate 240 and the circuit board). In some implementations, one or more of the connection structures 255 may provide both mechanical and electrical connections.

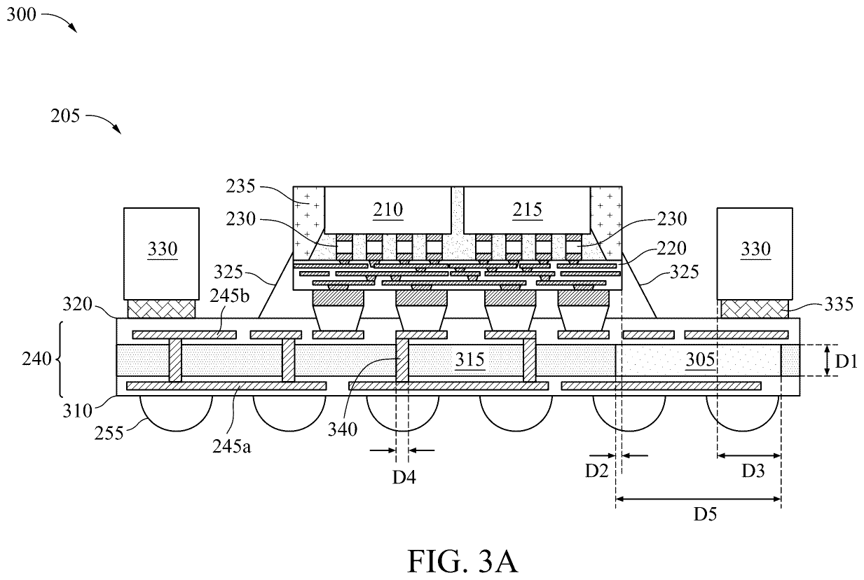

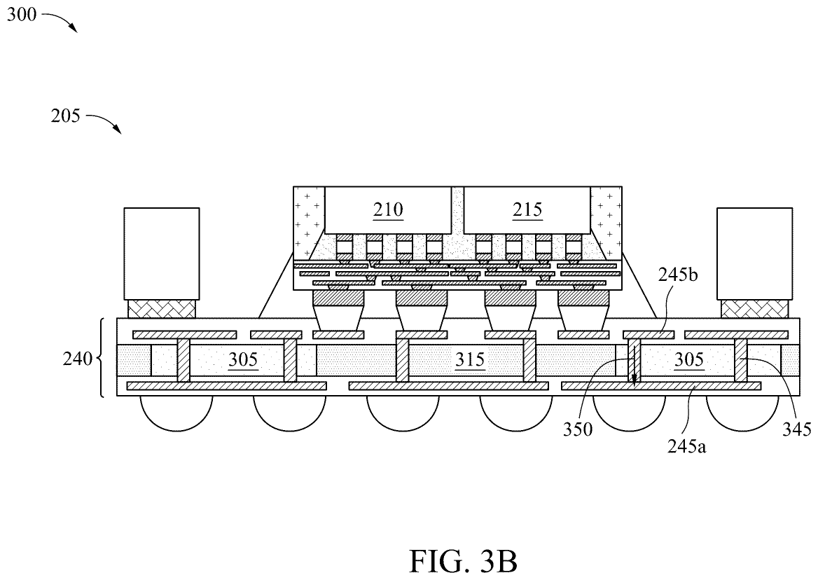

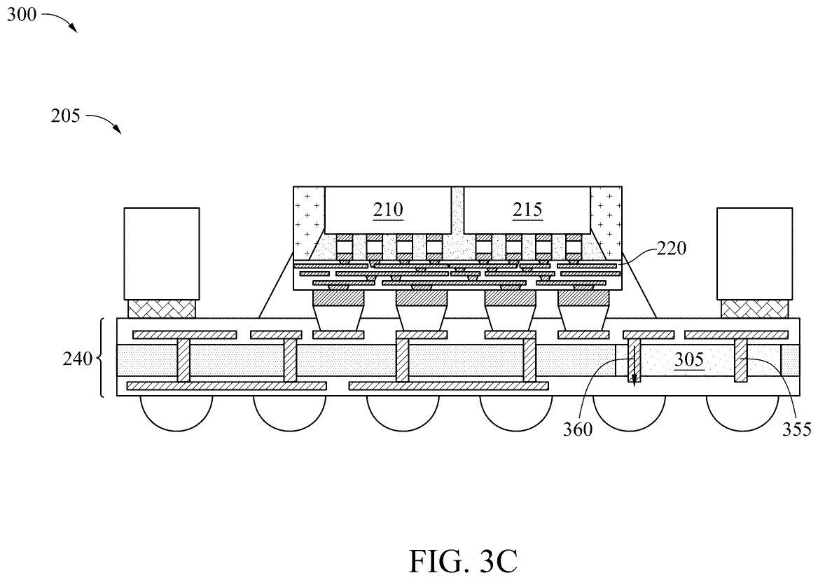

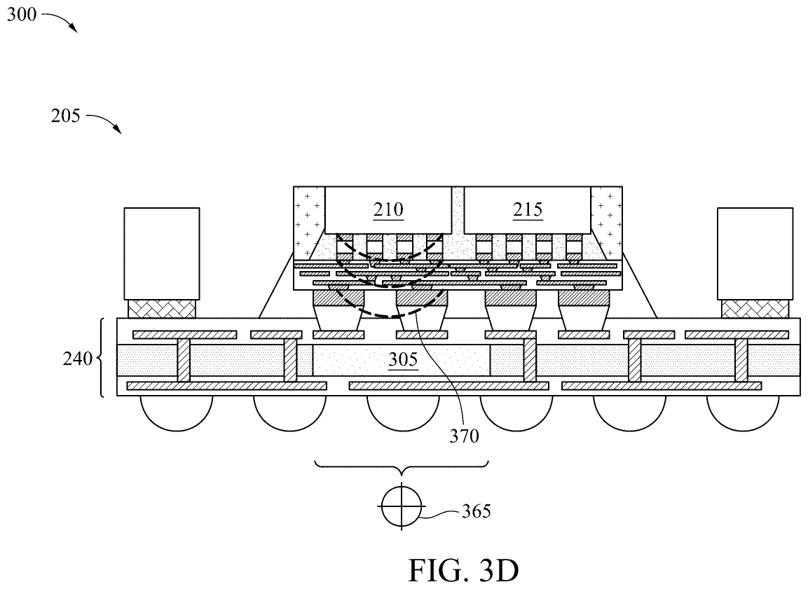

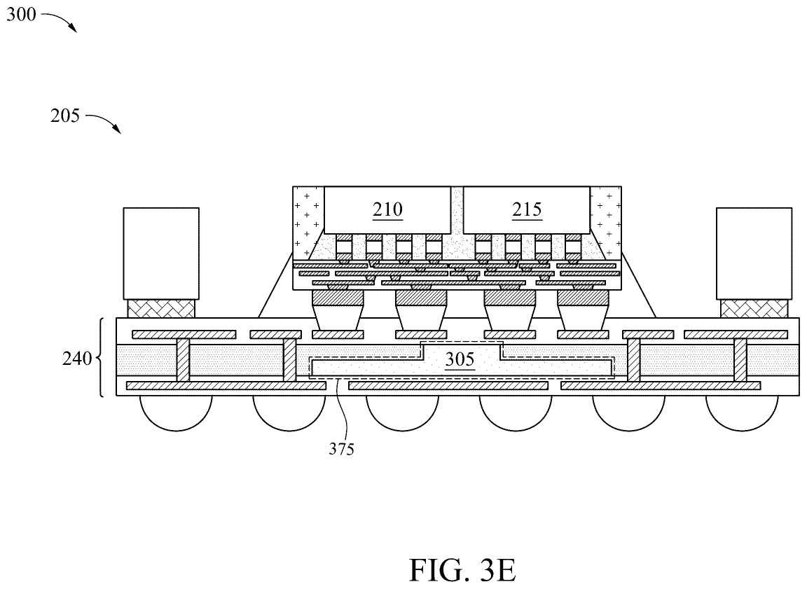

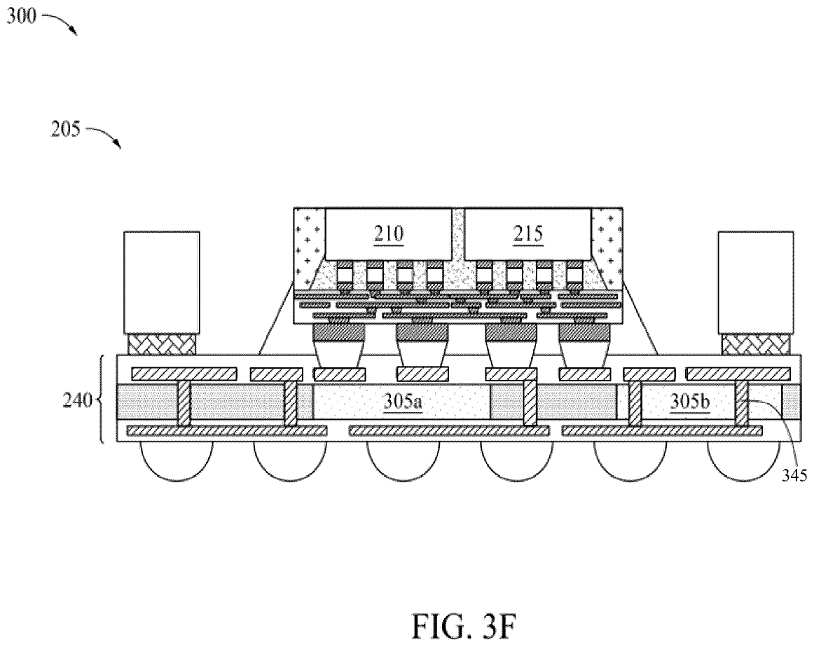

The semiconductor package 205 may include one or more additional features. As described in greater detail in connection with FIGS. 3A-6, and elsewhere herein, the semiconductor package 205 includes an interposer (e.g., the interposer 220) including a top surface and a bottom surface, and one or more IC dies (e.g., the SoC IC die 210 and the DRAM IC die 215, among other examples). In some implementations, the one or more IC dies are electrically and/or mechanically connected to the top surface of the interposer. The semiconductor package 205 includes a substrate (e.g., the substrate 240) including a top layer, a bottom layer, and at least one reinforcement structure between the top layer and the bottom layer, where at least one interconnect access structure electrically connects electrically-conductive traces (e.g., the electrically-conductive traces 245) of the top layer to electrically conductive traces of the bottom layer, where an aspect ratio of a width of the at least one reinforcement structure to a thickness of the at least one reinforcement structure is greater relative to an aspect ratio of a width of an interconnect access structure to a length of the interconnect access structure, and where the at least one reinforcement structure is configured to improve a rigidity of the semiconductor package to reduce a warpage of the substrate. The semiconductor package includes a plurality of connection structures (e.g., the connection structures 250) that electrically connect the substrate and the interposer.

Additionally, or alternatively, the semiconductor package 205 includes a substrate (e.g., the substrate 240) including a bottom core layer, a top core layer, a binding material layer between the top core layer and the bottom core layer, and a reinforcement structure embedded within the binding material layer to reduce a warpage of the substrate. In some implementations, the reinforcement structure is contiguous. The semiconductor package 205 includes a stiffener structure over the substrate. In some implementations, a portion of the stiffener structure overlaps a portion of the reinforcement structure.

As indicated above, FIG. 2 is provided as an example. Other examples may differ from what is described with regard to FIG. 2.

FIGS. 3A-3F are diagrams of an example implementation 300 described herein. Example implementation 300 may include one or more portions of the semiconductor package 205 formed using a combination of operations performed by one or more of the semiconductor processing tools 105-150 as described in connection with FIG. 1. In example implementation 300, the semiconductor package 205 includes at least one reinforcement structure 305.

As shown in FIG. 3A, the reinforcement structure 305 is embedded in the substrate 240. The reinforcement structure 305 may include a silicon material, a silicon-oxide material, a stainless steel material, or a copper material, among other examples. For example, reinforcement structure 305 may be a silicon substrate made from a wafer.

In some implementations, a body of the reinforcement structure 305 includes a dielectric (e.g., a non-electrically conductive) material. In such implementations, the reinforcement structure 305 may include electrically-conductive structures or electrically-conductive traces to transmit signals within the semiconductor package 205.

In some implementations, the body of the reinforcement structures 305 includes an electrically-conductive material. In such implementations, the reinforcement structure 305 may be electrically-isolated from electrically-conductive structures or electrically-conductive traces within the semiconductor package 205.

Additionally, or alternatively, the reinforcement structure 305 may include a material having a modulus of elasticity (e.g., a Young's modulus of elasticity) that is greater than approximately 50 gigapascals (GPa). If the material has a modulus of elasticity that is less than approximately 50 GPa, a measure of rigidity of the substrate 240 (and/or the semiconductor package 205) may not satisfy a threshold that prevents the substrate 240 (and/or the semiconductor package 205) from an unacceptable warpage during an SMT process.

The reinforcement structure 305 may increase a rigidity of the substrate 240 (and/or the semiconductor package 205) so that warpage and coplanarity thresholds are satisfied during the SMT process. In some implementations, and as an example, a warpage threshold of the substrate 240 (and/or the semiconductor package 205) is included in a range of approximately −0.14 millimeters to approximately +0.23 millimeters during reflow of materials (e.g., solder) during the SMT process. Additionally, or alternatively, a coplanarity threshold of the substrate 240 (and/or the semiconductor package 205) and a circuit board (to which the semiconductor package 205 may be attached) may be less than approximately 0.3 millimeters. However, other values and ranges for the warpage and coplanarity thresholds are within the scope of the present disclosure.

Maintaining such warpage and coplanarity thresholds reduces a likelihood that the connection structures 255 at the bottom surface of the substrate 240 will fail to adequately solder or attach to lands of the circuit board during the SMT process. Additionally, maintaining the warpage and coplanarity thresholds may increase a robustness of the connection structures 250 between the interposer 220 and the substrate 240 during the SMT process and/or a package reliability test (e.g., a thermal cycling test, among other examples).

To embed the reinforcement structure 305 in the substrate 240, one or more tools of the PCB tool set 140 (e.g., the laminating tool, the plating tool, the photoengraving tool, and/or the etching tool, among other examples) may perform a series of operations that include forming a bottom layer 310 (e.g., a bottom core layer) of the substrate 240. The bottom layer 310 of the substrate 240 may include electrically-conductive traces 245a (e.g., first electrically-conductive traces) routed through a first dielectric material (e.g., a fiberglass-epoxy laminate material or a buildup film material, among other examples).

One or more tools of the PCB tool set 140 may form a binding material layer 315 over the bottom layer 310. As an example, one or more tools of the PCB tool set 140 (e.g., the laminating tool) may laminate a layer of a pre-preg material (e.g., a fabric material pre-impregnated with a resin material) onto the bottom layer 310. Additionally, or alternatively, one or more tools of the PCB tool set 140 (e.g., the dispense tool) may dispense an epoxy material onto the bottom layer 310 to form the binding material layer 315.

In some implementations, one or more tools of the PCB tool set 140 (e.g., the laser cutting tool and/or the pick-and-place tool, among other examples) form the reinforcement structure 305 in the binding material layer 315. As an example, forming the reinforcement structure 305 in the binding material layer 315 may include forming a cavity in the binding material layer 315 and depositing the reinforcement structure 305 in the cavity.

As part of embedding the reinforcement structure 305 in the substrate 240, one or more tools of the PCB tool set 140 (e.g., the laminating tool, the plating tool, the photoengraving tool, and/or the etching tool, among other examples) may perform a series of operations that include forming a top layer 320 (e.g., a top core layer) over the binding material layer 315. The top layer 320 of the substrate 240 may include electrically-conductive traces 245b (e.g., second electrically-conductive traces) routed through a second dielectric material (e.g., a fiberglass-epoxy laminate material or a buildup film material, among other examples). The curing tool of the PCB tool set 140 may cure the bottom layer 310, the binding material layer 315, the reinforcement structure 305, and the top layer 320 at an elevated temperature to form the substrate 240.

The reinforcement structure 305 may, as shown in FIG. 3A, include a thickness D1. For example, the thickness D1 is included in a range of approximately 0.5 millimeters to approximately 1.5 millimeters. If the thickness is less than approximately 0.5 millimeters, an overall rigidity of the substrate 240 (and/or the semiconductor package 205) may not satisfy a threshold that prevents an unacceptable warpage of the semiconductor package 205 during an SMT process. If the thickness D1 is greater than approximately 1.5 millimeters, the reinforcement structure 305 may be thicker than the binding material layer 315 and be mechanically incompatible with the substrate 240. However, other values and ranges for the thickness D1 are within the scope of the present disclosure.

As shown in FIG. 3A, the semiconductor package 205 includes the SoC IC die 210 and the DRAM IC die 215 attached to the interposer 220 using the connection structures 230. In some implementations, one or more tools of the connection tool set 115 perform a combination of operations to form the connection structures 230 on a bottom surface of the SoC IC die 210, a bottom surface of the DRAM IC die 215, and/or a top surface of the interposer 220. One or more tools of the die-attach tool set 130 (e.g., the pick-and-place tool and the reflow tool, among other examples) may perform a combination of operations to attach the SoC IC die 210 and the DRAM IC die 215 to the interposer 220.

The interposer 220 is connected to the substrate 240 using the connection structures 250. In some implementations, one or more tools of the connection tool set 115 perform a combination of operations to form the connection structures 250 on a bottom surface of the interposer 220 and/or a top surface of the substrate 240. In some implementations, a pick-and-place tool and a reflow tool (e.g., the pick-and-place tool and the reflow tool of the die-attach tool set 130, among other examples) may attach the interposer 220 to the substrate 240.

In some implementations, and as shown in FIG. 3A, the reinforcement structure 305 includes a region that underlaps with the interposer 220 by a length D2. For example, the length D2 is included in a range of approximately 0.3 millimeters to approximately 1.5 millimeters. If the length D2 is less than approximately 0.3 millimeters, an overall rigidity of the substrate 240 (and/or the semiconductor package 205) may not satisfy a threshold that prevents an unacceptable warpage of the semiconductor package 205 during an SMT process. If the length D2 is greater than approximately 1.5 millimeters, the reinforcement structure 305 may encroach under a high-power region of one or more IC dies (e.g., the DRAM IC die 215) and reduce a thermal performance of the semiconductor package 205 and be mechanically incompatible with the substrate 240. However, other values and ranges for the length D2 are within the scope of the present disclosure.

In some implementations, and as shown in FIG. 3A, the semiconductor package 205 includes the mold compound 235 and an underfill material 325 (e.g., an epoxy polymer, among other examples). One or more tools of the encapsulation tool set 135 (e.g., the mold tool and the dispense tool, among other examples) may perform a combination of operations to form the mold compound 235 and the underfill material 325. The underfill material 325 may surround the connection structures 250 to improve a robustness of a connection between the interposer 220 and the substrate 240.

The semiconductor package 205 further includes a stiffener structure 330 mounted to a top surface of the substrate 240. The stiffener structure 330 may include a plastic material, an aluminum (Al) material, or a copper (Cu) material, among other examples. A pick-and-place tool (e.g., a pick- and place tool of the die-attach tool set 130, among other examples) may attach the stiffener structure 330 to the top surface of the substrate 240. An adhesive material 335 (e.g., an epoxy, among other examples) may be between the stiffener structure 330 and the top surface of the substrate 240.

In some implementations, and as shown in FIG. 3A, the reinforcement structure 305 includes a region that underlaps with the stiffener structure 330 by a length D3 (e.g., the stiffener structure 330 includes a region that overlaps with the reinforcement structure 305). For example, the length D3 is included in a range of approximately 1.0 millimeter to approximately 10.0 millimeters. If the length is less than approximately 1.0 millimeter, an overall rigidity of the substrate 240 (and/or the semiconductor package 205) may not satisfy a threshold that prevents an unacceptable warpage of the semiconductor package 205 during an SMT process. If the length D3 is greater than approximately 10.0 millimeters, the reinforcement structure 305 may extend beyond an edge boundary of the substrate 240 and be mechanically incompatible with the substrate 240. However, other values and ranges for the length D3 are within the scope of the present disclosure.

In some implementations, and as shown in FIG. 3A, the semiconductor package 205 includes interconnect access structure(s) 340 (e.g., a vertical interconnect access structures, among other examples) that electrically connect electrically-conductive traces of the top layer 320 to electrically-conductive traces of the bottom layer 310. In some implementations, an aspect ratio of the reinforcement structure 305 may be greater relative to an aspect ratio of the interconnect access structure(s) 340. For example, an aspect ratio of a width D5 of the reinforcement structure to the thickness D1 of the reinforcement structure 305 may be greater relative to an aspect ratio of a width D4 of the access structure(s) 340 to a length of the interconnect access structure(s) 340 (e.g., a length of the interconnect structure(s) 340 that corresponds to the thickness D1 of the reinforcement structure).

As shown in FIG. 3B, the semiconductor package 205 may include a plurality of instances of the reinforcement structure 305. As further shown in FIG. 3B, the reinforcement structure 305 may include one or more electrically-conductive structures 345 penetrating through the reinforcement structure 305 to transmit electrical signals 350 between electrically-conductive traces of the substrate 240 (e.g., the electrically-conductive traces 245a and 245b, among other examples). In some implementations, one or more of tools of the RDL tool set 105 (e.g., one or more of the photolithography tools, the deposition tools, and/or the etch tools, among other examples) may perform a combination of operations to form the one or more electrically-conductive structures 345. In some implementations, the one or more electrically-conductive structures 345 may correspond to vertical connection access structures (vias). In some implementations (e.g., as shown in connection with FIG. 3A), the reinforcement structure 305 does not include the one or more electrically-conductive structures 345 (e.g., the reinforcement structure 305 is contiguous).

As shown in FIG. 3C, the reinforcement structure 305 may include one or more thermally-conductive structures 355 to conduct heat 360 through the substrate 240. In some implementations, one or more of tools of the RDL tool set 105 (e.g., one or more of the photolithography tools, the deposition tools, and/or the etch tools, among other examples) may perform a combination of operations to form the one or more thermally-conductive structures 355. In some implementations, a location of the one or more thermally-conductive structures 355 may correspond to a location below an IC die (e.g., the SoC IC die 210 and/or the DRAM IC die 215), below another heat-generating device connected to the interposer 220, or above a heat sink structure (not shown), among other examples. The one or more thermally-conductive structures 355 may not be connected to electrically-conductive traces of the substrate 240 (e.g., the electrically-conductive traces 245a and 245b), and as such do not transmit electrical signals. In some implementations (e.g., as shown in connection with FIG. 3A), the reinforcement structure 305 does not include the one or more thermally-conductive structures 355 (e.g., the reinforcement structure 305 is contiguous).

As shown in FIG. 3D, the reinforcement structure 305 may be included at a location 365 (e.g., within the substrate 240) that is below at least one IC die (e.g., the SoC IC die 210, among other examples). The location 365 may enable the reinforcement structure 305 to shield an electromagnetic field 370 originating from the IC die.

As shown in FIG. 3E, the reinforcement structure 305 may include a cross-sectional shape 375 (e.g., a cross-sectional shape that is other than rectangular). The cross-sectional shape 375 may influence a moment of inertia of the reinforcement structure 305 under a bending load to the semiconductor package 205 (e.g., a flexure or bending within the semiconductor package 205). In some implementations, one or more dimensional properties of the cross-sectional shape 375 may be modified to achieve a desired moment of inertia of the reinforcement structure 305 (e.g., a desired resistance to the flexure or bending within the semiconductor package 205).

FIG. 3F shows an example configuration of the substrate 240 including a plurality of instances of the reinforcement structure 305 (e.g., a combination of the reinforcement structures 305 from FIGS. 3A-3E). As shown in FIG. 3F, more than one reinforcement structure 305 may be embedded in the substrate 240 (e.g., the reinforcement structure 305a and the reinforcement structure 305b). In some implementations, and as shown, the reinforcement structure 305a and the reinforcement structure 305b are at different locations within the substrate 240. Additionally, the reinforcement structure 305a is contiguous, while the reinforcement structure 305b includes electrically-conductive structures 345 (e.g., the reinforcement structure 305b is non-contiguous).

The number and arrangement of features of the semiconductor package 205 in FIGS. 3A-3F are provided as one or more examples. In practice, there may be additional features, different features, or differently arranged features than those shown in FIGS. 3A-3F.

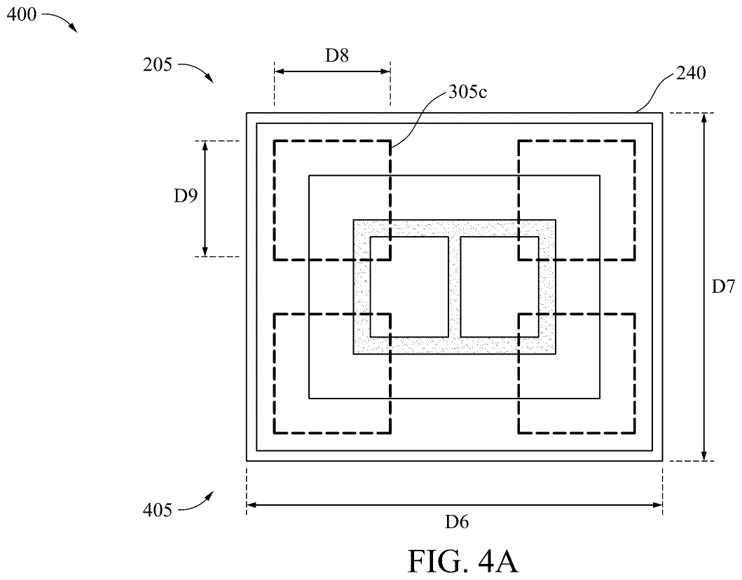

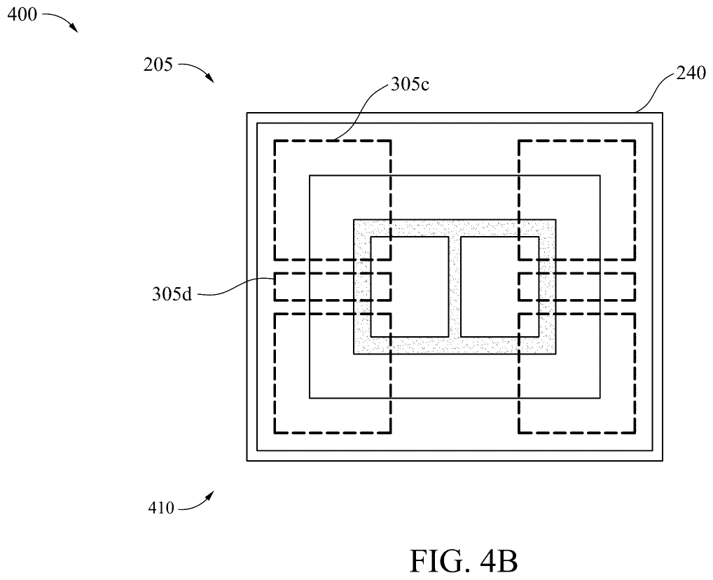

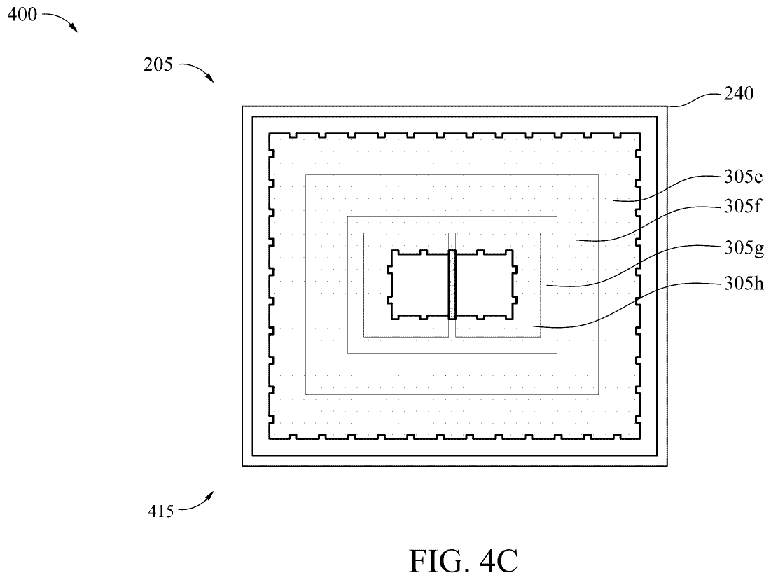

FIGS. 4A-4C are diagrams of an example implementation 400 described herein. The implementation 400 includes one or more example layout patterns that may be associated with the reinforcement structure 305 within the substrate 240 of the semiconductor package 205.

In FIG. 4A, the substrate 240 includes an example layout pattern 405, where the reinforcement structures 305c are located near approximate corners of the substrate 240. In the layout pattern 405, the substrate 240 includes a length D6 and a width D7. As an example, the length D6 is included in range of approximately 67.5 millimeters to approximately 72.5 millimeters. Additionally, or alternatively, the width D7 is included in a range of approximately 67.5 millimeters to approximately 72.5 millimeters. However, other values and ranges for the length D6 and the width D7 are within the scope of the present disclosure.

The one or more of the reinforcement structures 305c may have a length D8 and a width D9. For example, the length D8 is included in a range of approximately 5.0 millimeters to approximately 10.0 millimeters. Additionally, or alternatively, the width D9 is included in a range of approximately 5.0 millimeters to approximately 10.0 millimeters. If one or more of the length D8 and/or the width D9 are less than approximately 5.0 millimeters, an overall rigidity of the substrate 240 (and/or the semiconductor package 205) including the layout pattern 405 may not satisfy a threshold that prevents an unacceptable warpage of the semiconductor package 205 during an SMT process. If one or more of the length D8 and/or the width D9 are greater than approximately 10.0 millimeters, one or more of the reinforcement structures 305a may be mechanically incompatible with the layout pattern 405. However, other values and ranges for the length D8 and the width D9 are within the scope of the present disclosure.

In FIG. 4B, the substrate 240 includes an example layout pattern 410 including the reinforcement structures 305c located near approximate corners of the substrate 240. Additionally, the layout pattern 410 includes reinforcement structures 305d located near approximate edges of the substrate 240. In some implementations, using the layout pattern 410 in the semiconductor package 205 increases a rigidity of the substrate 240 (and/or the semiconductor package 205) relative to the using layout pattern 405.

As shown in FIG. 4C, the substrate 240 includes an example layout pattern 415 including one or more ring-shaped reinforcement structures 305e-305h around a periphery of the substrate 240. In some implementations, using the layout pattern 415 in the semiconductor package 205 increase a rigidity of the substrate 240 (and/or the semiconductor package 205) relative to using the layout patten 405 and/or the layout pattern 410.

In the example layout patterns 405-415, and in other layout patterns (not illustrated), the reinforcement structure 305 includes an area that is included in a range of approximately 1% of the area of the substrate 240 to approximately 30% of the area of the substrate 240. The area of the reinforcement structure 305 may be dependent on a layout pattern (e.g., one of the layout patterns 405-415, or another layout pattern). If the area of the reinforcement structure 305 is less than approximately 1% of the area of the substrate 240, a rigidity of the substrate 240 (and/or the semiconductor package 205) may not satisfy a threshold that prevents an unacceptable warpage of the semiconductor package 205 during an SMT process. If the area of the reinforcement structure 305 is greater than approximately 30% of the substrate 240, one or more of the reinforcement structures 305 may be mechanically incompatible with the layout pattern 405-415. However, other percentages or ratios of the area of the reinforcement structure 305 to the area of the substrate 240 are within the scope of the present disclosure.

The number and arrangement of features of the semiconductor package 205 in FIGS. 4A-4C are provided as one or more examples. In practice, there may be additional features, different features, or differently arranged features than those shown in FIGS. 4A-4C.

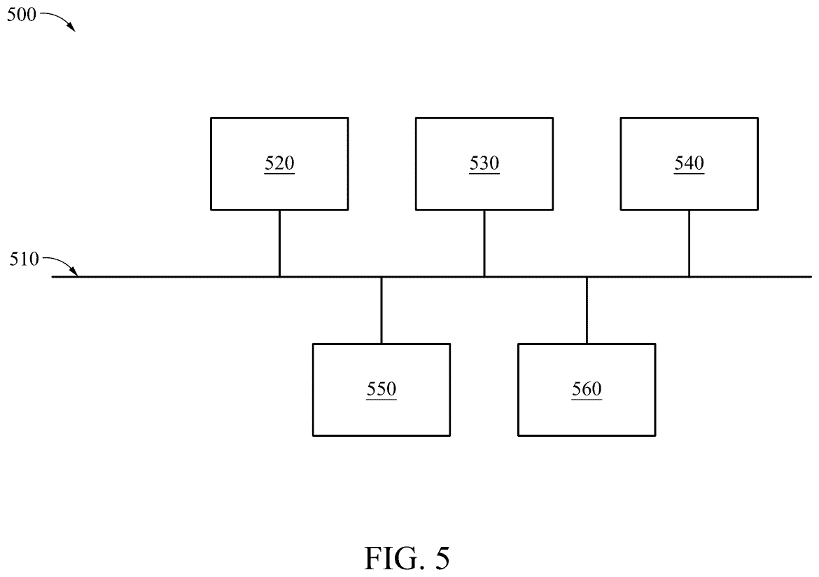

FIG. 5 is a diagram of example components of a device 500, which may correspond to one or more of the semiconductor processing tools 105-150. In some implementations, the semiconductor process tools 105-150 include one or more devices 500 and/or one or more components of device 500. As shown in FIG. 5, device 500 may include a bus 510, a processor 520, a memory 530, an input component 540, an output component 550, and a communication component 560.

Bus 510 includes one or more components that enable wired and/or wireless communication among the components of device 500. Bus 510 may couple together two or more components of FIG. 5, such as via operative coupling, communicative coupling, electronic coupling, and/or electric coupling. Processor 520 includes a central processing unit, a graphics processing unit, a microprocessor, a controller, a microcontroller, a digital signal processor, a field-programmable gate array, an application-specific integrated circuit, and/or another type of processing component. Processor 520 is implemented in hardware, firmware, or a combination of hardware and software. In some implementations, processor 520 includes one or more processors capable of being programmed to perform one or more operations or processes described elsewhere herein.

Memory 530 includes volatile and/or nonvolatile memory. For example, memory 530 may include random access memory (RAM), read only memory (ROM), a hard disk drive, and/or another type of memory (e.g., a flash memory, a magnetic memory, and/or an optical memory). Memory 530 may include internal memory (e.g., RAM, ROM, or a hard disk drive) and/or removable memory (e.g., removable via a universal serial bus connection). Memory 530 may be a non-transitory computer-readable medium. Memory 530 stores information, instructions, and/or software (e.g., one or more software applications) related to the operation of device 500. In some implementations, memory 530 includes one or more memories that are coupled to one or more processors (e.g., processor 520), such as via bus 510.

Input component 540 enables device 500 to receive input, such as user input and/or sensed input. For example, input component 540 may include a touch screen, a keyboard, a keypad, a mouse, a button, a microphone, a switch, a sensor, a global positioning system sensor, an accelerometer, a gyroscope, and/or an actuator. Output component 550 enables device 500 to provide output, such as via a display, a speaker, and/or a light-emitting diode. Communication component 560 enables device 500 to communicate with other devices via a wired connection and/or a wireless connection. For example, communication component 560 may include a receiver, a transmitter, a transceiver, a modem, a network interface card, and/or an antenna.

Device 500 may perform one or more operations or processes described herein. For example, a non-transitory computer-readable medium (e.g., memory 530) may store a set of instructions (e.g., one or more instructions or code) for execution by processor 520. Processor 520 may execute the set of instructions to perform one or more operations or processes described herein. In some implementations, execution of the set of instructions, by one or more processors 520, causes the one or more processors 520 and/or the device 500 to perform one or more operations or processes described herein. In some implementations, hardwired circuitry is used instead of or in combination with the instructions to perform one or more operations or processes described herein. Additionally, or alternatively, processor 520 may be configured to perform one or more operations or processes described herein. Thus, implementations described herein are not limited to any specific combination of hardware circuitry and software.

The number and arrangement of components shown in FIG. 5 are provided as an example. Device 500 may include additional components, fewer components, different components, or differently arranged components than those shown in FIG. 5. Additionally, or alternatively, a set of components (e.g., one or more components) of device 500 may perform one or more functions described as being performed by another set of components of device 500.

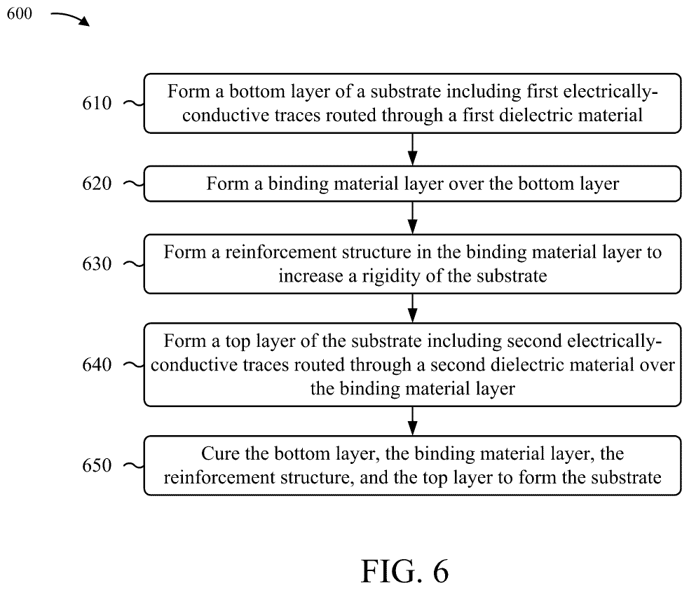

FIG. 6 is a flowchart of an example process associated with forming a semiconductor package described herein. In some implementations, one or more process blocks of FIG. 6 are performed by one or more of the semiconductor processing tool sets 105-150. Additionally, or alternatively, one or more process blocks of FIG. 6 may be performed by one or more components of device 500, such as processor 520, memory 530, input component 540, output component 550, and/or communication component 560.

As shown in FIG. 6, process 600 may include forming a bottom layer of a substrate including first electrically-conductive traces routed through a first dielectric material (block 610). For example, one or more of the semiconductor processing tool sets 105-150, such as the PCB tool set 140, may form a bottom layer 310 of a substrate 240 including first electrically-conductive traces 245a routed through a first dielectric material, as described above.

As further shown in FIG. 6, process 600 may include forming a binding material layer over the bottom layer (block 620). For example, one or more of the semiconductor processing tool sets 105-150, such as the PCB tool set 140, may form a binding material layer 315 over the bottom layer 310, as described above.

As further shown in FIG. 6, process 600 may include forming a reinforcement structure in the binding material layer to increase a rigidity of the substrate (block 630). For example, one or more of the semiconductor processing tool sets 105-150, such as the PCB tool set 140, may form a reinforcement structure 305 in the binding material layer 315 to increase a rigidity of the substrate 240, as described above.

As further shown in FIG. 6, process 600 may include forming a top layer of the substrate including second electrically-conductive traces routed through a second dielectric material over the binding material layer (block 640). For example, one or more of the semiconductor processing tool sets 105-150, such as the PCB tool set 140, may form a top layer 320 of the substrate 240 including second electrically-conductive 245b traces routed through a second dielectric material over the binding material layer 315, as described above.

As further shown in FIG. 6, process 600 may include curing the bottom layer, the binding material layer, the reinforcement structure, and the top layer to form the substrate (block 650). For example, one or more of the semiconductor processing tool sets 105-150, such as the PCB tool set 140, may cure the bottom layer 310, the binding material layer 315, the reinforcement structure 305, and the top layer 320 to form the substrate 240, as described above.

Process 600 may include additional implementations, such as any single implementation or any combination of implementations described below and/or in connection with one or more other processes described elsewhere herein.

In a first implementation, forming the reinforcement structure 305 in the binding material layer 315 includes forming a cavity in the binding material layer 315, and depositing the reinforcement structure 305 in the cavity.

In a second implementation, alone or in combination with the first implementation, forming the cavity in the binding material layer 315 includes forming the cavity using a laser to cut edges of the cavity.

In a third implementation, alone or in combination with one or more of the first and second implementations, process 600 includes connecting the substrate 240 to an interposer 220 of a semiconductor package 205.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

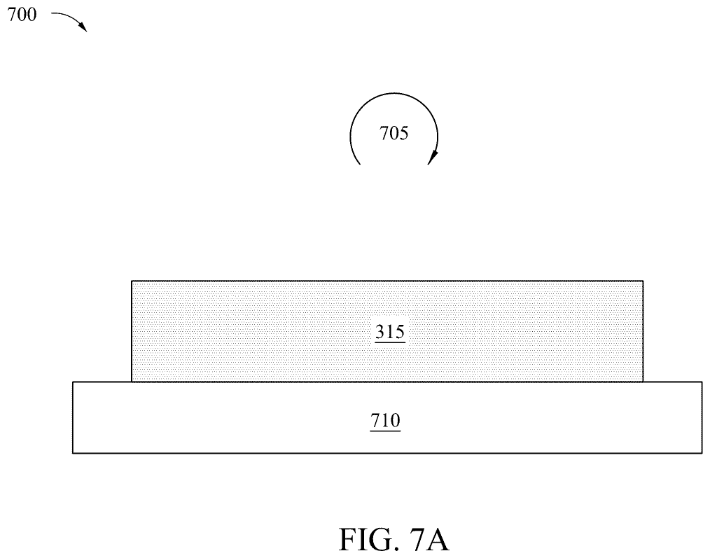

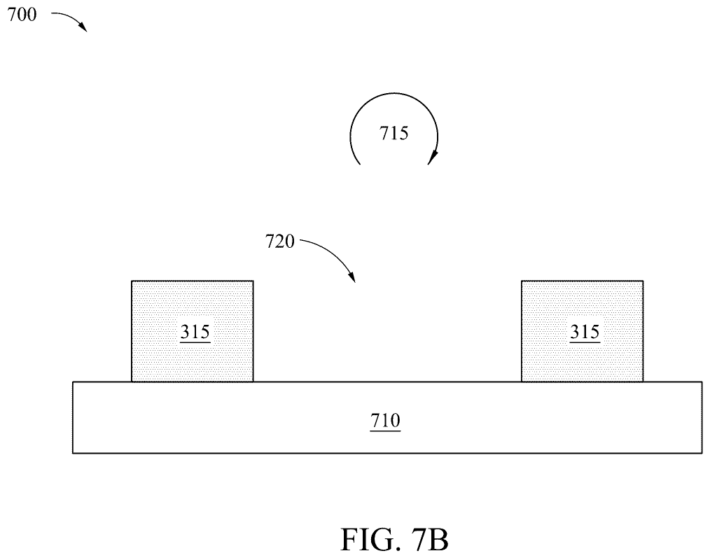

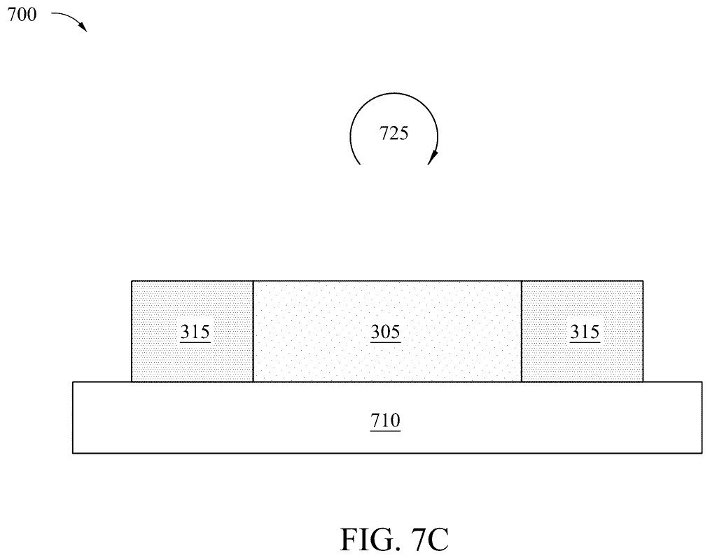

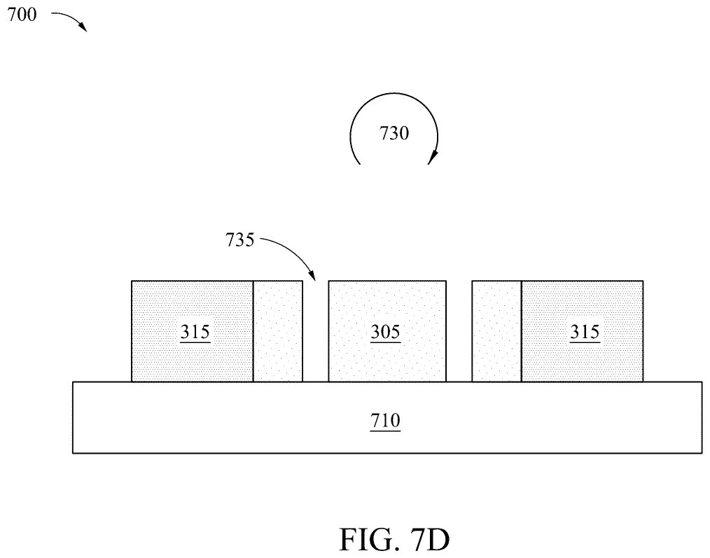

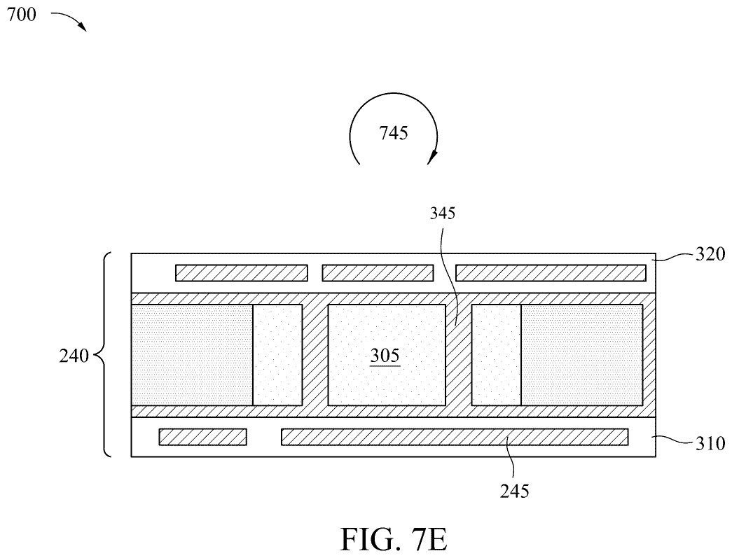

FIGS. 7A-7E are diagrams of an example implementation 700 described herein. The implementation 700 includes a series of operations that may be performed by the PCB tool set 140 to form the substrate 240 including the reinforcement structure 305. The implementation 700 may include one or more operations described in connection the process 600 of FIG. 6.

As shown in FIG. 7A, one or more tools of the PCB tool set 140 (e.g., the pick-and-place tool of the PCB tool set 140, among other examples) may perform a series of operations 705 that include placing the binding material layer 315 (e.g., a pre-formed segment of a pre-preg material or another core material, among other examples) on a temporary carrier 710. Additionally, or alternatively, the series of operations 705 may include one or more tools of the PCB tool set 140 (e.g., the lamination tool and the etching tool, among other examples) performing a lamination and etching operation to form the binding material layer 315 on the temporary carrier 710.

As shown in FIG. 7B, one or more tools of the PCB tool set 140 (e.g., the laser cutting tool or the etch tool of the PCB tool set 140, among other examples) may perform a series of operations 715 that include removing material from the binding material layer 315 to form a cavity 720 within the binding material layer 315.

As shown in FIG. 7C, one or more tools of the PCB tool set 140 (e.g., the pick-and-place tool of the PCB tool set 140, among other examples) may perform a series of operations 725 that include placing the reinforcement structure 305 (e.g., a pre-formed reinforcement structure) within the cavity 720.

In some implementations, the reinforcement structure 305 includes electrically-conductive structures and/or thermally-conductive structures (e.g., the electrically-conductive structures 345 and/or the thermally-conductive structures 355, among other examples). In such implementations, and as shown in FIG. 7D, one or more tools of the PCB tool set 140 (e.g., laser cutting tool or the etch tool of the PCB tool set 140, among other examples) may perform a series of operations 730 that include removing portions of the reinforcement structure 305 to form one or more through-holes 735 through the reinforcement structure 305.

As shown in FIG. 7E, one or more tools of the PCB tool set 140 (e.g., the lamination tool, the photoengraving tool, the etch tool, or the plating tool of the PCB tool set 140, among other examples) may perform a series of operations 745 to form the substrate 240 including the bottom layer 310 and the top layer 320. The series of operations 745 may include, for example, performing a plating operation to form electrically-conductive traces within the bottom layer 310 and the top layer 320, and to also form the electrically-conductive structures 345 penetrating through the reinforcement structure 305 (e.g., form the electrically-conductive structures 345 in the through-holes 735).

As indicated above, FIGS. 7A-7E are provided as examples. Other examples may differ from what is described with regard FIGS. 7A-7E, and include additional operations, fewer operations, differently arranged operations, different structures, or different materials than those described in connection with FIGS. 7A-7E.

Some implementations described herein provide techniques and apparatuses for a semiconductor package. The semiconductor package, which may correspond to an HPC package, includes a reinforcement structure that is embedded in a substrate of the semiconductor package. The reinforcement structure may increase a rigidity of the semiconductor package so that a warpage is reduced and a coplanarity between the substrate and a printed circuit board is maintained during a surface mount process.

Maintaining the coplanarity reduces a likelihood that connection structures at a bottom surface of the substrate will fail to adequately solder or attach to lands of the circuit board during a reflow process. Additionally, reducing the warpage may increase a robustness of connection structures formed between the interposer and the substrate. In this way, a likelihood of opens and/or shorts between the semiconductor package and the circuit board is reduced and a robustness of the semiconductor package may be increased to improve an overall yield of a product including the semiconductor package.

As described in greater detail above, some implementations described herein provide a semiconductor package. The semiconductor package includes an interposer including a top surface and a bottom surface. The semiconductor package includes one or more integrated circuit dies, where the one or more integrated circuit dies are electrically connected to the top surface of the interposer. The semiconductor package includes a substrate including a top layer, a bottom layer, and at least one reinforcement structure between the top layer and the bottom layer, where at least one interconnect access structure electrically connects electrically-conductive traces of the top layer to electrically conductive traces of the bottom layer, where an aspect ratio of a width of the at least one reinforcement structure to a thickness of the at least one reinforcement structure is greater relative to an aspect ratio of a width of an interconnect access structure to a length of the interconnect access structure, and where the at least one reinforcement structure is configured to improve a rigidity of the semiconductor package to reduce a warpage of the substrate. The semiconductor package includes a plurality of connection structures that electrically connect the substrate and the interposer.

As described in greater detail above, some implementations described herein provide a method. The method includes forming a bottom layer of a substrate including first electrically-conductive traces routed through a first dielectric material. The method includes forming a binding material layer over the bottom layer. The method includes forming a reinforcement structure in the binding material layer to increase a rigidity of the substrate. The method includes forming a top layer of the substrate including second electrically-conductive traces routed through a second dielectric material over the binding material layer. The method includes curing the bottom layer, the binding material layer, the reinforcement structure, and the top layer to form the substrate.

As described in greater detail above, some implementations described herein provide a semiconductor package. The semiconductor package includes a substrate including a bottom core layer, a top core layer, a binding material layer between the top core layer and the bottom core layer, and a reinforcement structure embedded within the binding material layer to reduce a warpage of the substrate, where the reinforcement structure is contiguous. The semiconductor package includes a stiffener structure over the substrate, where a portion of the stiffener structure overlaps a portion of the reinforcement structure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a bottom layer of a substrate including first electrically-conductive traces routed through a first dielectric material;
forming a binding material layer over the bottom layer;
forming a reinforcement structure in the binding material layer to increase a rigidity of the substrate;
forming a top layer of the substrate including second electrically-conductive traces routed through a second dielectric material over the binding material layer; and
curing the bottom layer, the binding material layer, the reinforcement structure, and the top layer to form the substrate.

2. The method of claim 1, wherein forming the reinforcement structure in the binding material layer comprises:
forming a cavity in the binding material layer; and
depositing the reinforcement structure in the cavity.

3. The method of claim 2, wherein forming the cavity in the binding material layer comprises:
forming the cavity using a laser to cut edges of the cavity.

4. The method of claim 1, further comprising:
connecting the substrate to an interposer of a semiconductor package.

5. A method, comprising:
forming a binding layer over a first layer that includes one or more first electrically-conductive traces;
forming a reinforcement structure within the binding layer;
forming a second layer, including one or more second electrically-conductive traces, over the reinforcement structure; and
curing the first layer, the binding layer, the reinforcement structure, and the second layer to form a substrate.

6. The method of claim 5, wherein the reinforcement structure is a pre-formed reinforcement structure.

7. The method of claim 5, wherein the reinforcement structure includes at least one of an electrically-conductive structure or a thermally-conductive structure.

8. The method of claim 5, wherein the one or more second electrically-conductive traces extend through the reinforcement structure.

9. The method of claim 5, further comprising:
mounting, after curing the first layer, the binding layer, the reinforcement structure, and the second layer, a stiffener structure to the substrate.

10. The method of claim 5, further comprising:
forming an interconnect access structure within the reinforcement structure, wherein the interconnect access structure electrically connects the one or more first electrically-conductive traces and the one or more second electrically-conductive traces.

11. The method of claim 10, wherein an aspect ratio of the reinforcement structure is greater relative to an aspect ratio of the interconnect access structure.

12. The method of claim 10, wherein an aspect ratio of a width of the reinforcement structure to a thickness of the reinforcement structure is greater relative to an aspect ratio of a width of the interconnect access structure to a length of the interconnect access structure.

13. A method, comprising:
forming a first layer that includes one or more first electrically-conductive traces;
forming one or more instances of a reinforcement structure over the first layer;
forming a second layer, including second electrically-conductive traces, over the one or more instances of the reinforcement structure; and
curing the first layer, the one or more instances of the reinforcement structures, and the second layer to form a substrate.

14. The method of claim 13, wherein the reinforcement structure includes a cross-sectional shape different from rectangular.

15. The method of claim 14, wherein the cross-section shape is a ring shape.

16. The method of claim 13, wherein the one or more instances of the reinforcement structure comprises a plurality of instances of the reinforcement structure.

17. The method of claim 16, wherein the plurality of instances of the reinforcement structure are on corners of the substrate.

18. The method of claim 14, wherein the reinforcement structure comprises a silicon material, a silicon-oxide material, a stainless steel material, or a copper material.

19. The method of claim 14, wherein the one or more instances of the reinforcement structure are formed in a binding layer.

20. The method of claim 14, wherein the first layer comprises a fiberglass-epoxy laminate material or a buildup film material, and wherein the second layer comprises a fiberglass-epoxy laminate material or a buildup film material.
